(19) United States
(12) Patent Application Publication
(10) Pub. No.: US 2026/0047208 A1
(43) Pub. Date: Feb. 12, 2026

(54) METHOD OF FABRICATING SEMICONDUCTOR DEVICE

(71) Applicant: SAMSUNG ELECTRONICS CO., LTD., Suwon-si (KR)

(72) Inventors: Cheolmin SHIN, Suwon-si (KR); Seongmin SON, Suwon-si (KR); Kyu-Ha LEE, Suwon-si (KR); Hyunkyung BAE, Suwon-si (KR); Ho-Jin LEE, Suwon-si (KR); Dong-Chan LIM, Suwon-si (KR)

(21) Appl. No.: 19/012,536

(22) Filed: Jan. 7, 2025

(30) Foreign Application Priority Data
Aug. 8, 2024 (KR) 10-2024-0106388

(51) Int. Cl. H10D 88/00; H01L 21/3105

(52) U.S. Cl. CPC H10D 88/01; H01L 21/31051

(57) ABSTRACT

A method of fabricating a semiconductor device includes forming a substrate and a wiring layer, forming a first interlayer insulating layer on the wiring layer, forming an etch stop layer covering a portion of an upper surface of the first interlayer insulating layer, forming a compensation insulating layer on the first interlayer insulating layer and the etch stop layer, planarizing the compensation insulating layer to form a compensation insulating pattern, forming a second interlayer insulating layer on the etch stop layer, and bonding the second interlayer insulating layer and a bonding wafer. The planarizing of the compensation insulating layer includes removing a portion of the compensation insulating layer to expose the etch stop layer.

### CROSS-REFERENCE TO RELATED APPLICATIONS

This U.S. non-provisional patent application claims priority under 35 U.S.C. § 119 to Korean Patent Application No. 10-2024-0106388, filed on Aug. 8, 2024 in the Korean Intellectual Property Office, the entire contents of which are hereby incorporated by reference.

### BACKGROUND

The inventive concept relates to a method of fabricating a semiconductor device, and more specifically, relates to a method of fabricating a semiconductor device including a bonding structure in which wafers are bonded.

Semiconductor devices are being highlighted as relevant elements in electronic industries due to their characteristics such as a small size, multi-functionality, and/or low manufacturing costs. The semiconductor devices may include semiconductor memory devices storing logic data, semiconductor logic devices calculating logic data, and hybrid semiconductor devices including a memory element and a logic element. To integrate the semiconductor devices, a bonding structure in which multiple wafers are bonded has been proposed, and research is being conducted to improve the yield of the semiconductor device manufacturing process while improving or reducing phenomenon of void in an edge region of the wafer.

### SUMMARY

An object of the inventive concept is to provide a method of fabricating a semiconductor device with improved manufacturing process yield.

Problems to be solved by the inventive concept are not limited to the problem(s) mentioned above, and other problems not mentioned may be clearly understood by those skilled in the art from the description below.

A method of fabricating a semiconductor device according to some embodiments of the inventive concept may include forming a substrate and a wiring layer, forming a first interlayer insulating layer on the wiring layer, forming an etch stop layer covering a portion of an upper surface of the first interlayer insulating layer, forming a compensation insulating layer on the first interlayer insulating layer and the etch stop layer, planarizing the compensation insulating layer to form a compensation insulating pattern, forming a second interlayer insulating layer on the etch stop layer, and bonding the second interlayer insulating layer and a bonding wafer, wherein planarizing the compensation insulating layer includes removing a portion of the compensation insulating layer to expose the etch stop layer.

A method of fabricating a semiconductor device according to some embodiments of the inventive concept may include preparing a sacrificial wafer, forming a substrate and a wiring layer on the sacrificial wafer, forming an insulating structure and an etch stop layer on the wiring layer, the insulating structure including a first interlayer insulating layer and a compensation insulating pattern, forming a second interlayer insulating layer on the insulating structure and the etch stop layer, and bonding the second interlayer insulating layer and a bonding wafer, wherein forming the insulating structure and the etch stop layer includes forming the first interlayer insulating layer on the wiring layer, forming the etch stop layer on the first interlayer insulating layer, forming a compensation insulating layer to cover the etch stop layer, and removing a portion of the compensation insulating layer to form the compensation insulating pattern, wherein removing the portion of the compensation insulating layer includes removing the portion of the compensation insulating layer so that a vertical level of an upper surface of the compensation insulating layer is lower than a vertical level of an upper surface of the etch stop layer.

A method of fabricating a semiconductor device according to some embodiments of the inventive concept may include forming a first stack structure, forming a second stack structure, and bonding the first stack structure and the second stack structure, wherein forming the first stack structure includes preparing a sacrificial wafer, forming a substrate and a wiring layer on the sacrificial wafer, forming a first interlayer insulating layer on the wiring layer, forming an etch stop layer on the first interlayer insulating layer, forming a compensation insulating layer on the first interlayer insulating layer and the etch stop layer, planarizing the compensation insulating layer until the etch stop layer is exposed to form a compensation insulating pattern, forming a second interlayer insulating layer on the etch stop layer, bonding the second interlayer insulating layer and a bonding wafer, and performing a slicing process on the sacrificial wafer, the substrate, the wiring layer, the first interlayer insulating layer, and the second interlayer insulating layer, wherein the compensation insulating pattern has a rounded shape, and wherein the slicing process is performed at a portion spaced apart from an edge of the sacrificial wafer toward a center region of the sacrificial wafer by 1.8 mm to 2.2 mm.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a cross-sectional view showing a semiconductor device according to embodiments of the inventive concept.

FIGS. 2, 3, 4A, 4B, 5, 6A, 6B, 7, and 8 illustrate a method of fabricating a semiconductor device according to embodiments of the inventive concept.

### DETAILED DESCRIPTION

Hereinafter, the inventive concept will be described in detail by explaining example embodiments of the inventive concept with reference to the attached drawings.

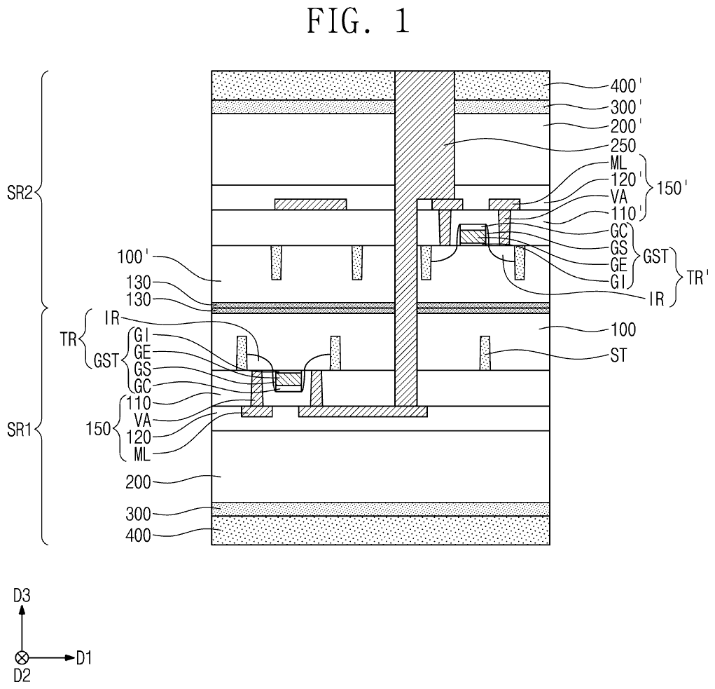

FIG. 1 is a cross-sectional view showing a semiconductor device according to embodiments of the inventive concept.

Referring to FIG. 1, a semiconductor device according to some embodiments of the inventive concept may include a first stack structure SR1 and a second stack structure SR2 stacked on the first stack structure SR1. The first stack structure SR1 and the second stack structure SR2 may be a portion of a wafer or a die.

The first stack structure SR1 may be provided. The first stack structure SR1 may include a substrate 100, a wiring layer 150, a first interlayer insulating layer 200, an etch stop layer 300, and a second interlayer insulating layer 400.

The substrate 100 may be a semiconductor substrate. The substrate 100 may be, for example, a silicon substrate, a silicon-germanium substrate, a germanium substrate, or a monocrystalline epitaxial layer grown on a monocrystalline silicon substrate.

A device isolation pattern ST defining an active region may be provided in the substrate 100. The device isolation pattern ST may include at least one of silicon oxide and silicon nitride.

A gate structure GST may be disposed on the substrate 100. The gate structure GST may include a gate insulating layer GI, a gate electrode GE on the gate insulating layer GI, a gate capping pattern GC on the gate electrode GE, and a gate spacer GS covering or surrounding sidewalls of each of the gate insulating layer GI, the gate electrode GE, and the gate capping pattern GC.

The gate insulating layer GI may include a silicon oxide layer, a silicon oxynitride layer, and/or a high-k layer. The high-k layer may include a high-k material having a higher dielectric constant than silicon oxide, such as hafnium oxide, hafnium silicon oxide, and hafnium zirconium oxide.

The gate capping pattern GC and the gate spacers GS may include at least one of silicon nitride, silicon oxynitride, and silicon oxycarbonitride.

A pair of impurity regions IR may be provided in the substrate 100. Each of the pair of impurity regions IR may correspond to source/drain regions. A pair of impurity regions IR may be disposed spaced apart from each other in the substrate 100 with the gate structure GST therebetween or as a center.

The gate structure GST and the pair of impurity regions IR may form a transistor TR. The transistor TR may be, for example, a transistor used to drive a memory device such as a dynamic random access memory (DRAM) or a flash memory. A type and arrangement of the transistor TR are not limited thereto and may be combined and changed in various ways depending on the type of the semiconductor device.

The wiring layer 150 may be disposed on the substrate 100. The wiring layer 150 may include a first insulating layer 110, a second insulating layer 120, wiring patterns ML, and a conductive via VA.

The first insulating layer 110 and the second insulating layer 120 may include, for example, silicon oxide. The conductive via VA may penetrate or extend through the first insulating layer 110. The wiring patterns ML may be provided in the second insulating layer 120. The conductive via VA may electrically connect the transistor TR and the wiring pattern ML. The wiring patterns ML and the conductive via VA may include a metal material. For example, the wiring patterns ML and the conductive via VA may include at least one of aluminum, copper, tungsten, molybdenum, ruthenium, and cobalt.

The first interlayer insulating layer 200 may be provided on the wiring layer 150. The first interlayer insulating layer 200 may include silicon oxide. For example, the first interlayer insulating layer 200 may be tetraethyl orthosilicate (TEOS, Si(OC₂H₅)₄).

The etch stop layer 300 may be provided on the first interlayer insulating layer 200. That is, the first interlayer insulating layer 200 may be disposed between the wiring layer 150 and the etch stop layer 300. The etch stop layer 300 may include a material having an etching selectivity with respect to the first interlayer insulating layer 200 and the second interlayer insulating layer 400. The etch stop layer 300 may include, for example, silicon nitride.

The second interlayer insulating layer 400 may be provided on the etch stop layer 300. That is, the etch stop layer 300 may be disposed between the first interlayer insulating layer 200 and the second interlayer insulating layer 400. The second interlayer insulating layer 400 may include silicon oxide. For example, the second interlayer insulating layer 400 may be tetraethyl orthosilicate (TEOS, Si(OC₂H₅)₄).

The second stack structure SR2 may be provided on the first stack structure SR1. The second stack structure SR2 may have a similar configuration to the first stack structure SR1. That is, the second stack structure SR2 may include a substrate 100′, a wiring layer 150′, a first interlayer insulating layer 200′, an etch stop layer 300′, and a second interlayer insulating layer 400′ as described in the first stack structure SR1. The substrate 100′, the wiring layer 150′, the first interlayer insulating layer 200′, the etch stop layer 300′, and the second interlayer insulating layer 400′ included in the second stack structure SR2 may be sequentially stacked on the first stack structure SR1.

According to some embodiments of the inventive concept, the first stack structure SR1 may include a cell circuit such as a memory integrated circuit. The cell circuit may include, for example, the transistor TR described in the first stack structure SR1. The second stack structure SR2 may include various peripheral circuits necessary for the operation of the cell circuit, and the peripheral circuits may be electrically connected to the cell circuit. The peripheral circuit may include, for example, the transistor TR′ of the second stack structure SR2.

A bonding oxide layer 130 may be provided between the first stack structure SR1 and the second stack structure SR2. The bonding oxide layer 130 may bond the first stack structure SR1 and the second stack structure SR2. The bonding oxide layer 130 may be a natural oxide layer formed from the substrate 100 of each of the stack structures SR1 and SR2.

A connection structure 250 may penetrate or extend through at least portions of the first stack structure SR1 and the second stack structure SR2. Specifically, the connection structure 250 may penetrate the second stack structure SR2, penetrate a portion of the first stack structure SR1, and extend to the wiring layer 150 of the first stack structure SR1. The connection structure 250 may have bottom surfaces disposed at different levels.

The above-mentioned connection structure 250 may electrically connect the first stack structure SR1 and the second stack structure SR2 by being in contact with the wiring pattern ML of the first stack structure SR1 and the wiring pattern ML of the second stack structure SR2. The above-mentioned connection structure 250 may include, for example, a metal material such as titanium or tungsten.

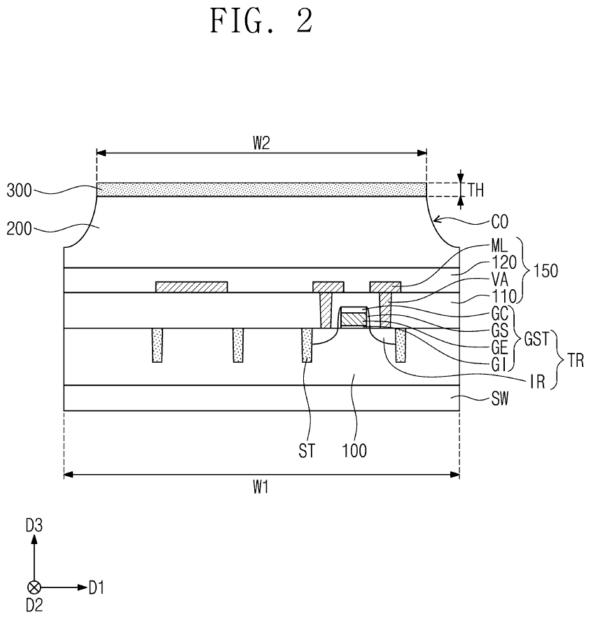

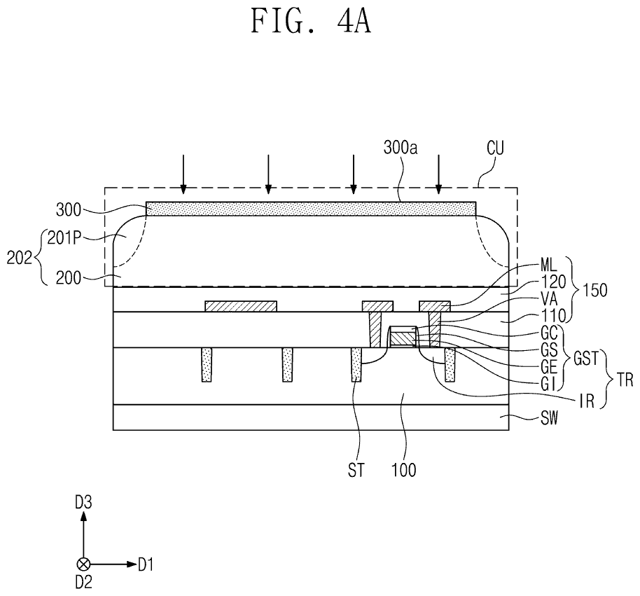

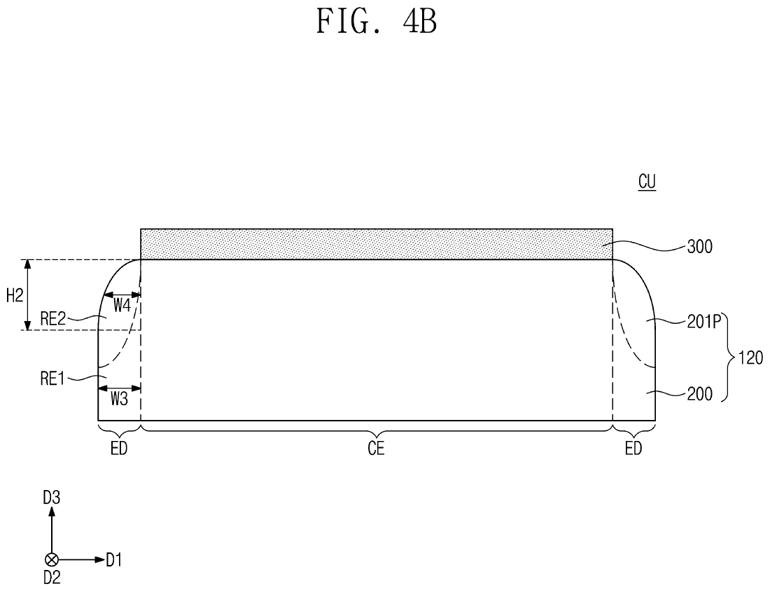

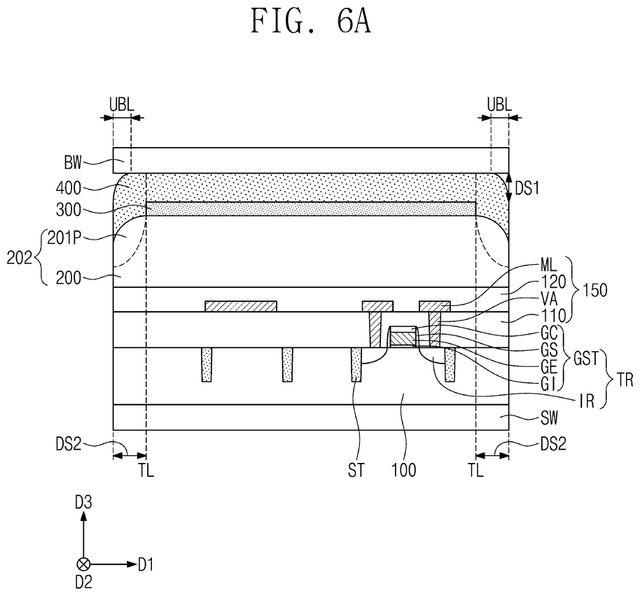

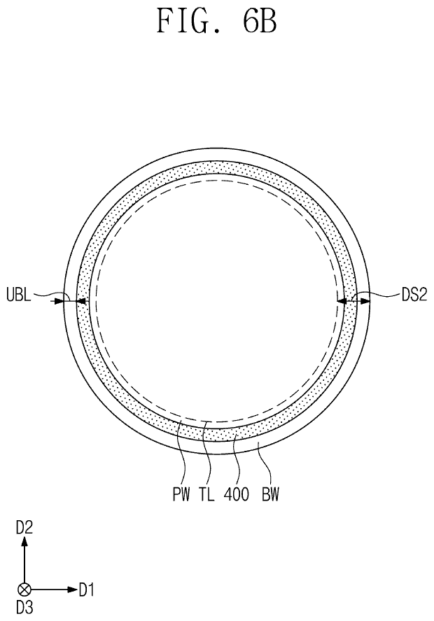

FIGS. 2, 3, 4A, 4B, 5, 6A, 7, and 8 are cross-sectional views for explaining a method of fabricating a semiconductor device according to embodiments of the inventive concept. Specifically, FIG. 4B is an enlarged view of portion ‘CU’ of FIG. 4A. FIG. 6B is a plan view of FIG. 6A. Descriptions overlapping with FIG. 1 may be omitted in the interest of brevity.

Referring to FIG. 2, a sacrificial wafer SW may be provided. The sacrificial wafer SW may be, for example, a bare silicon wafer. In this case, the sacrificial wafer SW may have a first width W1 in a first direction D1. The first width W1 may be, for example, 300 mm to 320 mm.

In this specification, the first direction D1 is defined as a direction parallel to an upper surface of the sacrificial wafer SW. A second direction D2 is defined as a direction parallel to the upper surface of the sacrificial wafer SW and perpendicular to the first direction D1. A third direction D3 is defined as a direction perpendicular to the upper surface of the sacrificial wafer SW.

A substrate 100 may be formed on the sacrificial wafer SW. A device isolation pattern ST may be formed in the substrate 100 and a transistor TR may be formed on the substrate 100. Thereafter, a wiring layer 150 may be formed on the substrate 100. The wiring layer 150 may include a first insulating layer 110, a second insulating layer 120, wiring patterns ML, and a conductive via VA.

A first interlayer insulating layer 200 may be formed on the wiring layer 150. The first interlayer insulating layer 200 may be formed through chemical vapor deposition (CVD), physical vapor deposition (PVD), atomic layer deposition (ALD), or the like.

In this case, the first interlayer insulating layer 200 may have a concave portion CO in an edge region due to stack dispersion accumulation of the substrate 100 and the wiring layer 150 provided below. The first interlayer insulating layer 200 may not have a constant thickness in the third direction D3 due to the concave portion CO. That is, the first interlayer insulating layer 200 may have an edge roll-off region. In this specification, the edge roll-off region means a portion where the edge region of the interlayer insulating layer is recessed.

An etch stop layer 300 may be formed on the first interlayer insulating layer 200. The edge region of the first interlayer insulating layer 200 may be exposed from the etch stop layer 300. That is, the etch stop layer 300 may cover a portion of an upper surface of the first interlayer insulating layer 200. The etch stop layer 300 may have a second width W2 in the first direction D1. The second width W2 of the etch stop layer 300 may be smaller than the first width W1 of the sacrificial wafer SW. The second width W2 may be, for example, 260 mm to 298 mm. A thickness TH of the etch stop layer 300 may be 10 Å to 1 μm.

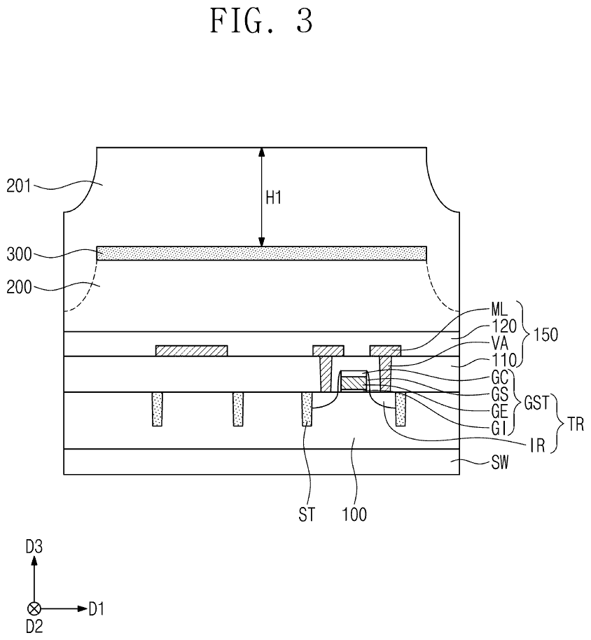

Referring to FIG. 3, a compensation insulating layer 201 may be formed to at least partially cover a side surface and an upper surface of the etch stop layer 300 and the edge region of the first interlayer insulating layer 200. Specifically, the compensation insulating layer 201 may fill the concave portion CO described in FIG. 2. That is, in the present specification, “compensation” may mean filling an insulating material to fill a portion where the edge region of the first interlayer insulating layer 200 is recessed. The compensation insulating layer 201 may have a first height H1 in the third direction D3 on the etch stop layer 300. The maximum value of the first height H1 may be, for example, 1 μm to 3 μm. The compensation insulating layer 201 may include the same material as the first interlayer insulating layer. The compensation insulating layer 201 may include silicon oxide. For example, the compensation insulating layer 201 may be tetraethyl orthosilicate (TEOS, Si(OC₂H₅)₄).

Referring to FIGS. 4A and 4B, a planarization process may be performed on the compensation insulating layer 201 until the upper surface of the etch stop layer 300 is exposed. That is, the planarization process may include removing a portion of the compensation insulating layer 201 until the upper surface of the etch stop layer 300 is exposed. Due to the process, a portion of the compensation insulating layer 201 may be removed, thereby forming a compensation insulating pattern 201P that may be formed from the compensation insulating layer 201. Removing a portion of the compensation insulating layer 201 may include removing the compensation insulating layer 201 so that a vertical level of an upper surface of the compensation insulating layer 201 is lower than a vertical level of the upper surface of the etch stop layer 300.

The compensation insulating pattern 201P may be provided on the edge region of the first interlayer insulating layer 200. The compensation insulating pattern 201P may have a rounded shape. As a result of performing the planarization process, an insulating structure 202 including the first interlayer insulating layer 200 and the compensation insulating pattern 201P may be formed. The planarization process may include, for example, a chemical mechanical planarization (CMP) process.

Referring to FIG. 4B, the insulating structure 202 may include a center region CE and edge regions ED connected to the center region CE. The center region CE may be provided between the edge regions ED. The edge regions ED may be regions corresponding to both sides of the insulating structure 202. Due to the planarization process, the edge region ED of the insulating structure 202 may have a rounded shape. That is, both sides of the insulating structure 202 may have an edge roll-off region.

A thickness of the edge region ED in the third direction D3 may be smaller than a thickness of the center region CE in the third direction D3. The thickness of the edge region ED in the third direction D3 may increase as the edge region approaches the center region CE in the first direction D1. The center region CE may be covered by the etch stop layer 300. The edge region ED may be exposed from the etch stop layer 300.

In this case, the edge region ED may include a first portion RE1 and a second portion RE2 on the first portion RE1. The first portion RE1 and the second portion RE2 may correspond to lower and upper portions of the edge region ED, respectively. The first portion RE1 may have a third width W3 in the first direction D1. The third width W3 may be constant regardless of the vertical level. The second portion RE2 may have a fourth width W4 in the first direction D1. The fourth width W4 may decrease as the second portion RE2 approaches the etch stop layer 300 in the third direction D3. The second portion RE2 may have a second height H2 in the third direction D3. The second height H2 may increase as the second portion RE2 approaches the center region CE in the first direction D1. The maximum value of the second height H2 may be, for example, 0.2 μm to 0.4 μm. That is, a recessed degree of the edge region ED of the insulating structure 202 may be at most 0.2 μm to 0.4 μm.

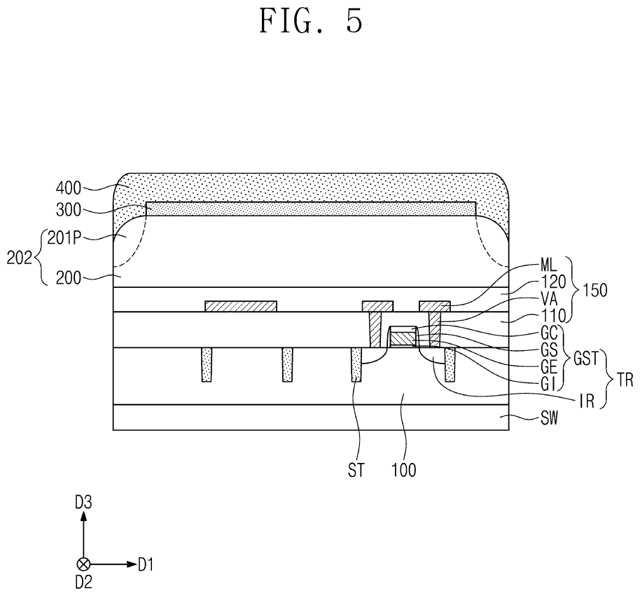

Referring to FIGS. 4A, 4B, and 5, a second interlayer insulating layer 400 may be formed on the insulating structure 202 and the etch stop layer 300. That is, the etch stop layer 300 may be disposed between the first interlayer insulating layer 200 and the second interlayer insulating layer 400. The second interlayer insulating layer 400 may at least partially cover the compensation insulating pattern 201P and the etch stop layer 300.

A shape of the second interlayer insulating layer 400 may be similar to the shape of the insulating structure 202 described in FIG. 4B. Specifically, due to the planarization process for the compensation insulating layer 201, the edge region of the second interlayer insulating layer 400 formed on the insulating structure 202 may also have a rounded shape, corresponding to the rounded shape of the compensation insulating pattern 201P. That is, both sides of the second interlayer insulating layer 400 may have an edge roll-off region. The second interlayer insulating layer 400 may be formed through chemical vapor deposition (CVD), physical vapor deposition (PVD), or atomic layer deposition (ALD).

Referring to FIGS. 6A and 6B, a bonding wafer BW may be bonded to a portion of the second interlayer insulating layer 400. The bonding wafer BW may be, for example, a bare silicon wafer. Specifically, as described in FIG. 5, as the edge region of the second interlayer insulating layer 400 has an edge roll-off region, the edge region of the second interlayer insulating layer 400 may not be bonded to the bonding wafer BW. A length or width UBL of the region where the second interlayer insulating layer 400 and the bonding wafer BW are not bonded may be, for example, 1.5 mm to 1.7 mm.

On the edge region of the second interlayer insulating layer 400, the maximum separation distance in the third direction D3 between the second interlayer insulating layer 400 and the bonding wafer BW may have a first distance DS1. The first distance DS1 may be, for example, 0.2 μm to 0.4 μm.

Thereafter, a removal process may be performed on the sacrificial wafer SW, the substrate 100, the wiring layer 150, the first interlayer insulating layer 200, and the second interlayer insulating layer 400. The removal process may include, for example, a slicing process such as laser trimming. The removal process may be performed along a slicing line TL. The slicing line TL may be formed at a portion moved from the edge of the sacrificial wafer SW to the center region by a second distance DS2 in the first direction D1. When viewed in a plan view, as shown in FIG. 6B, the slicing line TL may have a circular shape. The second distance DS2 may be 1.8 mm to 2.2 mm. According to some embodiments, the second distance DS2 may be 1.9 mm. As the second distance DS2 is formed to be 2.2 mm or less, components included in the substrate 100 and the wiring layer 150 may not be damaged or removed, thereby improving yield of the semiconductor device manufacturing process.

As a result of performing the above removal process, widths of the sacrificial wafer SW, the substrate 100, the wiring layer 150, the first interlayer insulating layer 200, and the second interlayer insulating layer 400 in the first direction D1 may be reduced. According to some embodiments, the compensation insulating pattern 201P may also be partially or entirely removed by the removal process.

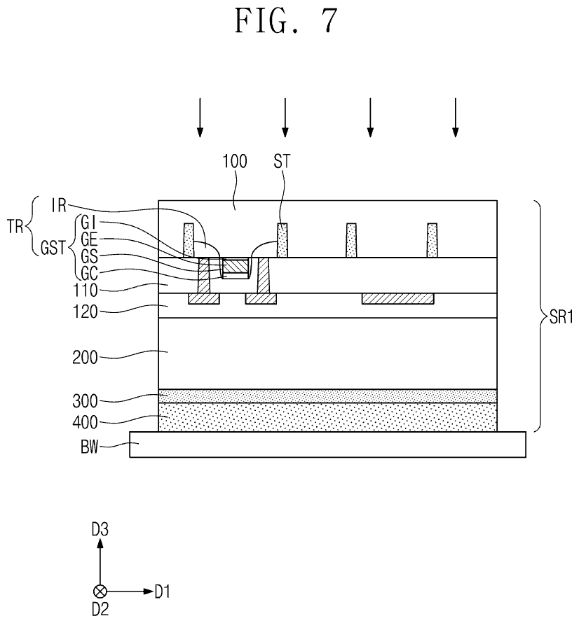

Referring to FIG. 7, the sacrificial wafer SW, the substrate 100, the wiring layer 150, the first interlayer insulating layer 200, the etch stop layer 300, the second interlayer insulating layer 400, and the bonding wafer BW may be turned over so that a bottom surface of the sacrificial wafer SW is exposed. Thereafter, the sacrificial wafer SW may be removed. Removing the sacrificial wafer SW may be performed, for example, by a grinding process. As the sacrificial wafer SW is removed, the substrate 100 may be exposed, and a first stack structure SR1 including the substrate 100, the wiring layer 150, the first interlayer insulating layer 200, the etch stop layer 300, the second interlayer insulating layer 400, and the bonding wafer BW may be formed.

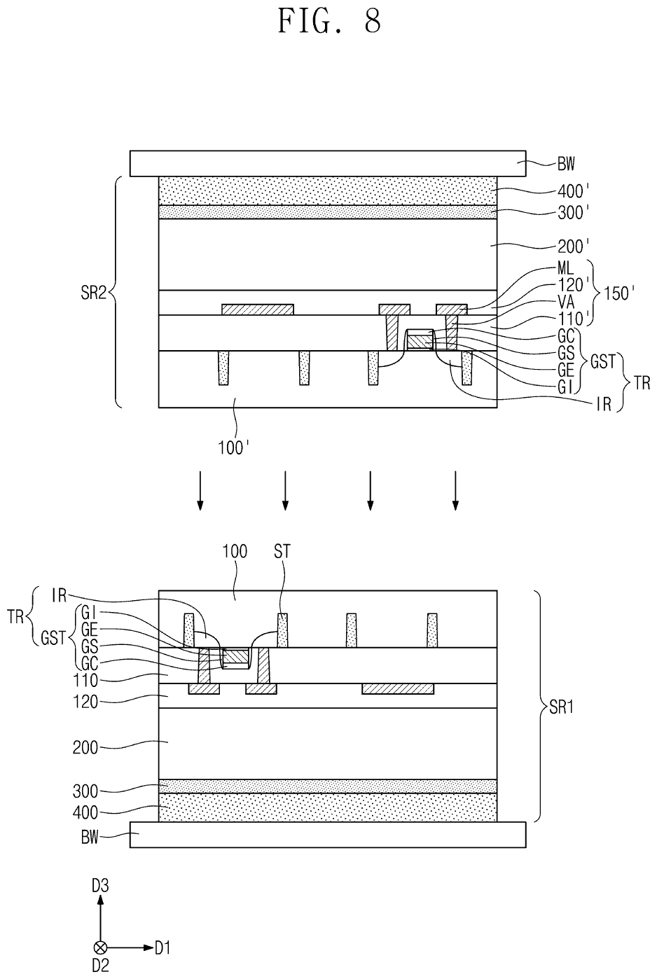

Referring to FIG. 8, a second stack structure SR2 may be bonded on the first stack structure SR1. The components of the second stack structure SR2 may be similar to the components of the first stack structure SR1. That is, the second stack structure SR2 may also include a substrate 100′, a wiring layer 150′, a first interlayer insulating layer 200′, an etch stop layer 300′, a second interlayer insulating layer 400′, and a bonding wafer BW. The second stack structure SR2 may be formed through a process substantially identical or similar to that of forming the first stack structure SR1 in FIGS. 2 to 7.

Thereafter, referring back to FIG. 1, the bonding wafer BW on the first stack structure SR2 and the second stack structure SR2 may be removed. After removing the bonding wafer BW, a connection structure 250 penetrating a portion of the first stack structure SR1 and the second stack structure SR2 may be formed, thereby completing a semiconductor device according to some embodiments of the inventive concept.

According to a method of fabricating a semiconductor device of the comparative example, a planarization process on the interlayer insulating layer was performed before bonding the wafer on the interlayer insulating layer. However, in this case, a void occurred at the bonding portion, resulting in a chipping phenomenon in which the wafer was broken. To eliminate the void occurrence phenomenon, even when the edge region of the interlayer insulating layer was recessed, the recessed degree of the edge region was 1 μm or more due to the stack dispersion of the lower wafer, etc. As a result, the length of the unbonded portion between the interlayer insulating layer and the wafer increased. As a result, as the slicing process had to be performed inside the unbonded portion of the interlayer insulating layer and the wafer, yield of the semiconductor device manufacturing process was reduced.

On the other hand, the method of fabricating the semiconductor device according to embodiments of the inventive concept may include forming the etch stop layer on the interlayer insulating layer, forming the compensation insulating layer to cover the etch stop layer, and performing the planarization process on the compensation insulating layer. In this case, the edge region of the interlayer insulating layer may be exposed from the etch stop layer, and the width of the etch stop layer may be smaller than the width of the wafer. Due to the etch stop layer and the compensation insulating layer, a step difference of the edge region of the interlayer insulating layer may be adjusted, and the recessed degree of the edge region may be adjusted to a range of 0.2 μm to 0.4 μm. As a result, the phenomenon of void generation near the bonding between the interlayer insulating layer and the wafer may be prevented, and as the length of the unbonded region between the interlayer insulating layer and the wafer may be reduced, thereby improving the yield of the semiconductor device manufacturing process.

The method of fabricating the semiconductor device according to embodiments of the inventive concept may include forming the etch stop layer on the interlayer insulating layer, forming the compensation insulating layer to cover the etch stop layer, and performing the planarization process on the compensation insulating layer. In this case, the edge region of the interlayer insulating layer may be exposed from the etch stop layer, and the width of the etch stop layer may be smaller than the width of the wafer. Due to the etch stop layer and the compensation insulating layer, the step difference of the edge region of the interlayer insulating layer may be adjusted, and the recessed degree of the edge region may be adjusted to a range of 0.2 μm to 0.4 μm. As a result, the void occurrence phenomenon may be prevented near the bonding between the interlayer insulating layer and the wafer, and the length of the unbonded region between the interlayer insulating layer and the wafer may be reduced, thereby improving the yield of the semiconductor device manufacturing process.

While example embodiments are described above, a person skilled in the art may understand that many modifications and variations are made without departing from the spirit and scope of the inventive concept defined in the following claims. Accordingly, the example embodiments of the inventive concept should be considered in all respects as illustrative and not restrictive, with the spirit and scope of the inventive concept being indicated by the appended claims.

What is claimed is:

1. A method of fabricating a semiconductor device, the method comprising
forming a substrate and a wiring layer;
forming a first interlayer insulating layer on the wiring layer;
forming an etch stop layer covering a portion of an upper surface of the first interlayer insulating layer;
forming a compensation insulating layer on the first interlayer insulating layer and the etch stop layer;
planarizing the compensation insulating layer to form a compensation insulating pattern;
forming a second interlayer insulating layer on the etch stop layer; and
bonding the second interlayer insulating layer and a bonding wafer,
wherein planarizing the compensation insulating layer includes removing a portion of the compensation insulating layer to expose the etch stop layer.

2. The method of claim 1, wherein the compensation insulating pattern is on an edge region of the first interlayer insulating layer, and
wherein the compensation insulating pattern has a rounded shape.

3. The method of claim 2, wherein the second interlayer insulating layer covers upper surfaces of the compensation insulating pattern and the etch stop layer.

4. The method of claim 2, wherein an edge region of the second interlayer insulating layer has a rounded shape.

5. The method of claim 1, wherein the etch stop layer has a thickness of 10 Å to 1 μm.

6. The method of claim 1, wherein the first interlayer insulating layer, the compensation insulating layer, and the second interlayer insulating layer include silicon oxide, and
wherein the etch stop layer includes silicon nitride.

7. The method of claim 1, wherein forming the compensation insulating layer includes forming the compensation insulating layer to have a height of 1 μm to 3 μm on the etch stop layer.

8. The method of claim 1, further comprising:
preparing a sacrificial wafer before forming the wiring layer; and
placing the substrate on the sacrificial wafer.

9. The method of claim 8, wherein the sacrificial wafer has a first width in a first direction parallel to an upper surface of the substrate,
wherein the etch stop layer has a second width in the first direction, and
wherein the second width is smaller than the first width.

10. The method of claim 9, wherein the second width is 260 mm to 298 mm.

11. A method of fabricating a semiconductor device, the method comprising:
preparing a sacrificial wafer;
forming a substrate and a wiring layer on the sacrificial wafer;
forming an insulating structure and an etch stop layer on the wiring layer, the insulating structure including a first interlayer insulating layer and a compensation insulating pattern;
forming a second interlayer insulating layer on the insulating structure and the etch stop layer; and
bonding the second interlayer insulating layer and a bonding wafer,
wherein forming the insulating structure and the etch stop layer includes:
forming the first interlayer insulating layer on the wiring layer;
forming the etch stop layer on the first interlayer insulating layer;
forming a compensation insulating layer to cover the etch stop layer; and
removing a portion of the compensation insulating layer to form the compensation insulating pattern, and
wherein removing the portion of the compensation insulating layer includes removing the portion of the compensation insulating layer so that a vertical level of an upper surface of the compensation insulating layer is lower than a vertical level of an upper surface of the etch stop layer.

12. The method of claim 11, wherein the insulating structure includes a center region and an edge region connected to the center region,
wherein the edge region includes a first portion and a second portion on the first portion,
wherein the second portion has a first width in a first direction,
wherein the first width decreases as the second portion approaches the etch stop layer, and
wherein a maximum height of the second portion is 0.2 μm to 0.4 μm.

13. The method of claim 12, wherein the center region is covered by the etch stop layer, and
wherein the edge region is exposed from the etch stop layer.

14. The method of claim 12, wherein the first portion has a second width in the first direction, and
wherein the second width is constant regardless of a vertical level.

15. The method of claim 12, wherein a height of the second portion increases as the second portion approaches the center region in the first direction.

16. A method of fabricating a semiconductor device, the method comprising:
forming a first stack structure;
forming a second stack structure; and
bonding the first stack structure and the second stack structure,
wherein forming the first stack structure includes:
preparing a sacrificial wafer;
forming a substrate and a wiring layer on the sacrificial wafer;
forming a first interlayer insulating layer on the wiring layer;
forming an etch stop layer on the first interlayer insulating layer;
forming a compensation insulating layer on the first interlayer insulating layer and the etch stop layer;
planarizing the compensation insulating layer until the etch stop layer is exposed to form a compensation insulating pattern;
forming a second interlayer insulating layer on the etch stop layer;
bonding the second interlayer insulating layer and a bonding wafer; and
performing a slicing process on the sacrificial wafer, the substrate, the wiring layer, the first interlayer insulating layer, and the second interlayer insulating layer,
wherein the compensation insulating pattern has a rounded shape, and
wherein the slicing process is performed at a portion spaced from an edge of the sacrificial wafer toward a center region of the sacrificial wafer by 1.8 mm to 2.2 mm.

17. The method of claim 16, wherein forming the first stack structure further includes flipping the sacrificial wafer over and removing the sacrificial wafer, after the slicing process.

18. The method of claim 17, further comprising forming a through-electrode penetrating the first stack structure and the second stack structure.

19. The method of claim 16, wherein the etch stop layer is disposed between the first interlayer insulating layer and the second interlayer insulating layer.

20. The method of claim 16, wherein an edge region of the second interlayer insulating layer has a rounded shape, and
wherein a maximum distance between the second interlayer insulating layer and the bonding wafer on the edge region of the second interlayer insulating layer is 0.2 μm to 0.4 μm.
